(19) United States
(12) Patent Application Publication
(10) Pub. No.: US 2019/0232582 A1
(43) Pub. Date: Aug. 1, 2019

(54) Composite Materials, and Systems and Methods for Making Composite Materials

(71) Applicant: The Boeing Company, Chicago, IL (US)

(72) Inventors: Andrew Nowak, Los Angeles, CA (US); Adam Gross, Malibu, CA (US); Richard Edward Sharp, Weldon Spring, MO (US); Michael Gervasoni, San Diego, CA (US)

(21) Appl. No.: 15/882,759

(22) Filed: Jan. 29, 2018

(51) Int. Cl. B29C 71/00; B29C 35/08; H05K 9/00

(52) U.S. Cl. CPC B29C 71/0072; B29C 35/0805; B29K 2505/08; B29C 2035/0827; H05K 9/0083

(57) ABSTRACT

In an example, a method of forming a composite material includes embedding a plurality of conductive-magnetic particles in a matrix material. The method also includes applying, using a magnetic device, a magnetic field to the plurality of conductive-magnetic particles in the matrix material to move the plurality of conductive-magnetic particles into an alignment in which a longitudinal axis of each conductive-magnetic particle is parallel to a direction of the magnetic field. The method further includes, while applying the magnetic field, curing the matrix material to a hardened state in which the alignment of the plurality of conductive-magnetic particles is fixed in the matrix material.

### FIELD

The present disclosure generally relates to composite materials, and more particularly to composite materials having electromagnetic interference (EMI) shielding properties.

### BACKGROUND

Electromagnetic interference (EMI) is an electromagnetic field and/or an electrostatic field generated by an external source that negatively affects an electrical circuit by electromagnetic induction, electrostatic coupling, or conduction. Aerial vehicles and aerospace vehicles may encounter EMI generated by a wide variety of sources. For instance, EMI may be generated by environmental conditions (e.g., lighting, solar flares, and/or an electrostatic discharge) or electrical devices on or near the vehicle (e.g., cell phones, laptop computers, tablet computers, antennas, and/or toys). In some instances, the EMI can negatively affect performance of electrical equipment on the vehicle. For example, on an aircraft, EMI can affect cockpit radios and radar signals, interfering with communication between a pilot and a control tower.

To mitigate the effects of EMI on avionic and aerospace equipment performance, some aerial vehicles and aerospace vehicles include devices that provide EMI shielding to electrical equipment. EMI shielding is the practice of reducing (or preventing) an electromagnetic field in a space by blocking the field with a barrier made of conductive and/or magnetic materials. One approach to EMI shielding is to house the electrical equipment in an enclosure made from dense, continuous sheets of metal or a mesh cage of metal. However, these EMI shielding enclosures tend to be relatively heavy, which reduces the fuel efficiency and flight range of the aerial vehicle or aerospace vehicle.

### SUMMARY

In an example, a method of forming a composite material is described that includes embedding a plurality of conductive-magnetic particles in a matrix material. The method also includes applying, using a magnetic device, a magnetic field to the plurality of conductive-magnetic particles in the matrix material to move the plurality of conductive-magnetic particles into an alignment in which a longitudinal axis of each conductive-magnetic particle is parallel to a direction of the magnetic field. The method further includes, while applying the magnetic field, curing the matrix material to a hardened state in which the alignment of the plurality of conductive-magnetic particles is fixed in the matrix material.

In another example, a composite material is described that includes a matrix material. The composite material also includes a plurality of conductive-magnetic particles embedded in the matrix material and in an alignment in which a longitudinal axis of each conductive-magnetic particle is parallel to a common direction relative to a surface of the composite material. Each conductive-magnetic particle has a length that is greater than a diameter of the conductive-magnetic particle. The longitudinal axis is parallel to the length. The matrix material electrically isolates the plurality of conductive-magnetic particles from each other.

In another example, a system for forming a composite material is described that includes a mold configured to contain a composite mixture comprising a plurality of conductive-magnetic particles embedded in a matrix material, a magnetic device configured to apply a magnetic field to the composite mixture in the mold, and a housing. The housing includes a first compartment configured to receive the mold, and a second compartment configured to receive the magnetic device. The first compartment and the second compartment are arranged relative to each other such that a direction of the magnetic field is substantially perpendicular to a surface of the mold, which forms a surface of the composite material.

The features, functions, and advantages that have been discussed can be achieved independently in various embodiments or may be combined in yet other embodiments further details of which can be seen with reference to the following description and drawings.

### BRIEF DESCRIPTION OF THE FIGURES

The novel features believed characteristic of the illustrative embodiments are set forth in the appended claims. The illustrative embodiments, however, as well as a preferred mode of use, further objectives and descriptions thereof, will best be understood by reference to the following detailed description of an illustrative embodiment of the present disclosure when read in conjunction with the accompanying drawings, wherein:

FIG. 1 illustrates a cross-sectional view of a composite material, according to an example embodiment.

FIG. 2 illustrates a simplified block diagram of a system for forming a composite material, according to an example embodiment.

FIG. 3 illustrates a perspective view of a system for forming a composite material, according to an example embodiment.

FIG. 4A illustrates a cross-sectional view of a composite material at a first stage of a manufacturing process, according to an example embodiment.

FIG. 4B illustrates a cross-sectional view of the composite material of FIG. 4A at a second stage of the manufacturing process, according to an example embodiment.

FIG. 5 illustrates a flow chart of an example process for forming a composite material, according to an example embodiment.

FIG. 6 illustrates a flow chart of an example process for forming a composite material that can be used with the process shown in FIG. 5.

FIG. 7 illustrates a flow chart of an example process for forming a composite material that can be used with the process shown in FIG. 5.

FIG. 8 illustrates a flow chart of an example process for forming a composite material that can be used with the process shown in FIG. 5.

FIG. 9 illustrates a flow chart of an example process for forming a composite material that can be used with the process shown in FIG. 5.

### DETAILED DESCRIPTION

Disclosed embodiments will now be described more fully hereinafter with reference to the accompanying drawings, in which some, but not all of the disclosed embodiments are shown. Indeed, several different embodiments may be described and should not be construed as limited to the embodiments set forth herein. Rather, these embodiments are described so that this disclosure will be thorough and complete and will fully convey the scope of the disclosure to those skilled in the art.

The systems and methods of the present disclosure provide for composite materials having EMI shielding properties. Specifically, the present disclosure provide for a composite material having a plurality of conductive-magnetic particles embedded in a matrix material. The conductive-magnetic particles provide the composite material with EMI shielding properties, whereas the matrix material binds the conductive-magnetic particles in a particular alignment relative to each other and/or a surface of the composite material. For instance, the conductive-magnetic particles can have an electrical conductivity and a magnetic permeability, which can dissipate and/or absorb the electric and/or magnetic fields of EMI incident on the composite material.

Within examples, the conductive-magnetic particles can each have a relatively high aspect ratio of length to diameter such that a longitudinal axis of the conductive-magnetic particle is parallel to the length. Additionally, within examples, the conductive-magnetic particles are in an alignment in which the longitudinal axis of each conductive-magnetic particle is parallel to a common direction relative to a surface of the composite material. For instance, in one example, the conductive-magnetic particles can be in an alignment in which the longitudinal axis of each conductive-magnetic particle is perpendicular to the surface of the composite material. As described in further detail below, providing the conductive-magnetic particles with a relatively high aspect ratio and/or aligning the conductive-magnetic particles in a common direction (e.g., perpendicular to the surface of the composite material) can provide for a relatively light weight and flexible composite material having EMI shielding properties.

Within examples, the composite material can be used for avionics packaging, enclosure shielding, radio packaging, canopy/window perimeters, structure gaps, and access cover plates. Additionally or alternatively, the composite material can provide a coating, which can be coupled to an enclosure to isolate an electrical device within the enclosure from EMI external to the enclosure and/or to limit a transmission of EMI from the electrical device within the enclosure so as to protect devices external to the enclosure. In another example, the composite material can be coupled to a cable and/or a wire to protect the wire from external EMI and/or to limit transmission of EMI from the cable and/or wire to other devices.

Additionally, the systems and methods of the present disclosure provide for forming the composite material with the conductive-magnetic particles in a specific alignment. Within examples, the conductive-magnetic particles can be aligned in a desired direction by applying a magnetic field to the conductive-magnetic particles while the matrix material cures from an uncured state to a hardened state. Specifically, the conductive-magnetic particles have a magnetic characteristic such that, when the magnetic field is applied to the conductive-magnetic particles, the conductive-magnetic particles move into an alignment in which a longitudinal axis of each conductive-magnetic particle is parallel to a direction of the magnetic field.

In the uncured state, the matrix material has a relatively low viscosity in the uncured state, which allows the conductive-magnetic particles to move within the matrix material responsive to the magnetic field. After the conductive-magnetic particles are moved into the desired alignment, the matrix material is cured to the hardened state while the magnetic field remains applied to the conductive-magnetic particles. In the hardened state, the alignment of the conductive-magnetic particles is fixed in the matrix material. Thus, after the matrix material cures to the hardened state, the conductive-magnetic particles remain in the alignment even when the magnetic field is no longer applied.

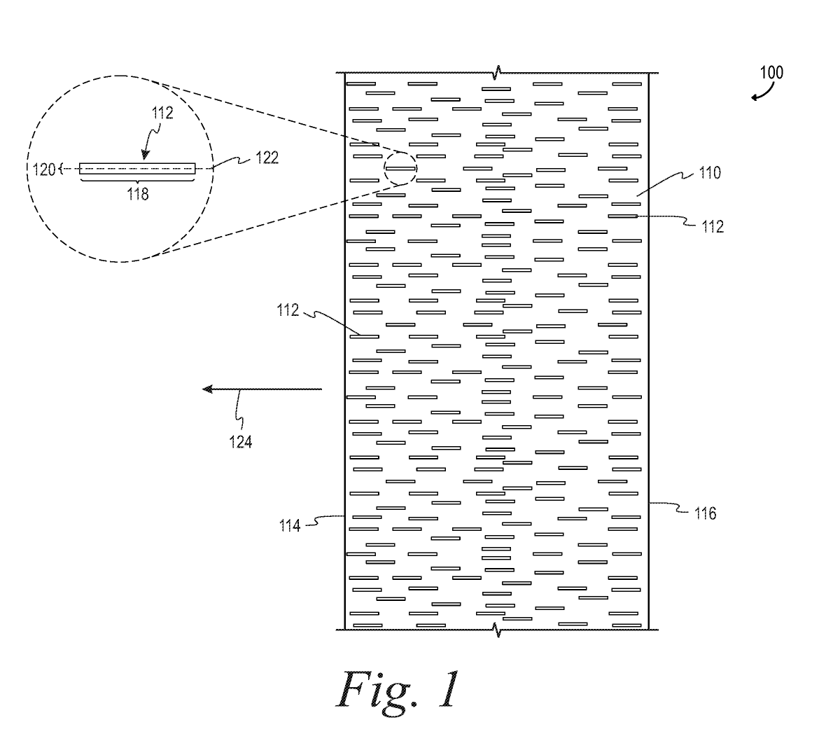

Referring now to FIG. 1, a cross-sectional view of a composite material 100 is depicted according to an example embodiment. As shown in FIG. 1, the composite material 100 includes a matrix material 110 and a plurality of conductive-magnetic particles 112 embedded in the matrix material 110. In FIG. 1, the composite material 100 is in the form of a sheet having planar surfaces 114, 116, which are parallel to each other. However, in other examples, the composite material 100 can have a different shape and/or size than that shown in FIG. 1.

The matrix material 110 is an electrical insulator, which binds the conductive-magnetic particles 112 in a particular alignment relative to each other and/or at least one of the surfaces 114, 116 of the composite material 100. Within examples, the matrix material 110 can be made from a resin such as, for example, silicone, urethane, acrylate, and/or a low-viscosity epoxy. In an uncured state, the matrix material 110 can have a relatively low viscosity to facilitate arranging the conductive-magnetic particles 112 into a particular alignment and/or position within the matrix material 110 during manufacture of the composite material 100. A relatively low viscosity allows for a relatively weak magnetic field strength to be applied to the conductive-magnetic particles 112 to achieve the alignment of the conductive-magnetic particles 112. The viscosity and other characteristics of the matrix material 110 are described in further detail below.

Within examples, when the matrix material 110 is cured to a hardened state, the matrix material 110 can be rigid or flexible. In implementations in which the matrix material 110 is flexible in the hardened state, the composite material 100 can conform to the shape of a housing or surface of an electronic device to be shielded from EMI by the composite material 100. For instance, the composite material 100 can be in the form of a coating, which can couple to the housing or surface of the electronic device.

As noted above, the conductive-magnetic particles 112 provide the composite material 100 with EMI shielding properties. In general, the conductive-magnetic particle 112 are reinforcement fibers of the composite material 100 having an electrical conductivity and a magnetic permeability, which can dissipate and/or absorb the electric and/or magnetic fields of EMI incident on the composite material 100. Within examples, the conductive-magnetic particles 112 can include a metallic material. For instance, the conductive-magnetic particles 112 can include nickel, copper, titanium, iron, cobalt, aluminum, chromium molybdenum, vanadium, and/or alloys of such metals. In another example, the conductive-magnetic particles 112 can be a metallic material within an insulating material. The insulating material may be an inorganic oxide like silica, alumina, titanium oxide, zirconium oxide or hafnium oxide. The insulating material may be an organic material that contains carbon, hydrogen, and optionally carbon such as poly(propylene glycol), poly(ethylene glycol), or polystyrene.

As shown in FIG. 1, each conductive-magnetic particle 112 has a length 118 that is greater than a diameter 120 of the conductive-magnetic particle 112. As such, each conductive-magnetic particle 112 has a longitudinal axis 122, which is parallel to the length 118. In one example, the length 118 of each conductive-magnetic particle 112 along the longitudinal axis 122 is between approximately 50 microns and approximately 5 millimeters, and the diameter 120 of each conductive-magnetic particle 112 is between approximately 0.1 microns and approximately 100 microns. For instance, in one implementation, each conductive-magnetic particle 112 can have a length of approximately 0.25 millimeters and a diameter of approximately 10 microns. By the term “approximately,” with reference to amounts or measurement values, it is meant that the recited characteristic, parameter, or value need not be achieved exactly. Rather, deviations or variations, including, for example, tolerances, measurement error, measurement accuracy limitations, and other factors known to those skilled in the art, may occur in amounts that do not preclude the effect that the characteristic was intended to provide.

Within examples, each conductive-magnetic particle 112 can have a relatively high aspect ratio of the length 118 to the diameter 120. For instance, in one example, the conductive-magnetic particles 112 each have an aspect ratio of the length 118 to the diameter 120 that is greater than two. In other examples, the aspect ratio can be greater than 2.5, greater than three, greater than four, greater than five, greater than 10, greater than 15, or greater than 20. A relatively high aspect ratio of the length 118 to the diameter 120 can beneficially provide for efficient packing of the conductive-magnetic particles 112 in the matrix material 110, which can allow the conductive-magnetic particles 112 to be embedded more densely in the matrix material 110. This can assist in reducing (or minimizing) gaps between the conductive-magnetic particles 112 and thereby enhance the EMI shielding properties of the composite material 100.

In another example, the aspect ratio can be greater than 25. Typically, as the aspect ratio increases, it was expected that it would be harder to align the conductive-magnetic particles 112 because the conductive-magnetic particles 112 would tend to jam (i.e., the conductive-magnetic particles 112 entangle responsive to an applied magnetic field). However, it was surprising that alignment of the conductive-magnetic particles was achieved using the processes described herein.

In FIG. 1, each conductive-magnetic particle 112 is rod-shaped. In other examples, however, the conductive-magnetic particles 112 can have other shapes such as, for instance, a wire, a rectangular prism, a hexagonal prism, a cylinder, and/or an elliptic cylinder. In examples in which a cross-section of each conductive-magnetic particle 112 is not circular, the aspect ratio described above can relate to an aspect ratio of the length 118 relative to a cross-sectional dimension, which is perpendicular to the length 118 (e.g., a width and/or a height), of the conductive-magnetic particle 112.

As shown in FIG. 1, the conductive-magnetic particles 112 are in an alignment in which the longitudinal axis 122 of each conductive-magnetic particle 112 is parallel to a common direction 124 relative to the surface 114 of the composite material 100. In an arrangement in which the longitudinal axis 122 of each conductive-magnetic particle 112 is parallel to the common direction 124, the conductive-magnetic particles 112 can be provided with a relatively high density while maintaining the matrix material 110 as an electrical insulator between the conductive-magnetic particles 112. This in turn can, among other things, assist in reducing (or minimizing) gaps between the conductive-magnetic particles 112 and thereby enhancing the EMI shielding properties of the composite material 100.

In FIG. 1, the common direction 124 is substantially perpendicular to the surface 114 of the composite material 100. By the term “substantially” it is meant that the recited characteristic, parameter, or value need not be achieved exactly, but that deviations or variations, including for example, tolerances, measurement error, measurement accuracy limitations and other factors known to skill in the art, may occur in amounts that do not preclude the effect the characteristic was intended to provide.

Aligning the longitudinal axis 122 of the conductive-magnetic particles 112 substantially perpendicular to the surface 114 of the composite material 100 can enhance the EMI shielding properties of the composite material 100. For instance, with the longitudinal axis 122 substantially perpendicular to the surface 114 of the composite material 100, the conductive-magnetic particles 112 can be relatively closely aligned with a magnetic field of EMI incident on the surface 114. As such, this alignment can facilitate generating eddy currents in the conductive-magnetic particles 112 to damp out an applied magnetic field component of the EMI incident on the surface 114 of the composite material 100. The alignment of the conductive-magnetic particles 112 can result in a more square magnetic hysteresis curve when the applied magnetic field from the EMI is parallel to the longitudinal axis 122 of the conductive-magnetic particles 112. This, in turn, results in a higher permeability and more efficient damping of EMI than other alignments.

Additionally, with the longitudinal axis 122 of each conductive-magnetic particle 112 aligned in the common direction 124 substantially perpendicular to the surface 114 of the composite material 100, the size, shape, and orientation of the gaps between the conductive-magnetic particles 112 can be arranged to reduce (or minimize) EMI transmission through the composite material 100 of one polarization of EMI.

Although it can be beneficial to arrange the conductive-magnetic particles 112 such that the longitudinal axis 122 of each conductive-magnetic particle 112 is substantially perpendicular to the surface 114 of the composite material 100, the conductive-magnetic particles 112 can be aligned with the longitudinal axes 122 parallel to another direction in other examples. For instance, in another example, the conductive particles 112 can be in an alignment in which the longitudinal axes 122 are within approximately 10 degrees from the direction 124 perpendicular to the surface 114 of the composite material 100. In another example, the conductive particles 112 can be in an alignment in which the longitudinal axes 122 are within approximately 20 degrees from the direction 124 perpendicular to the surface 114 of the composite material 100.

In one example, the conductive-magnetic particles 112 are approximately 10% to approximately 50% of the volume of the composite material 100. It has been found that a fractional volume of approximately 10% to approximately 50% conductive-magnetic particles 112 in the composite material 100 can beneficially provide EMI damping without loss of alignment of the conductive-magnetic particles 112. Generally, EMI damping is proportional to the mass fraction of the conductive-magnetic particles 112 so higher loadings result in a smaller volume of the matrix material 110, which can present challenges in aligning the conductive-magnetic particles 112. Additionally, for example, this fractional volume can provide effective shielding performance with reduced weights relative to purely metal EMI shielding materials. In another example, the conductive-magnetic particles 112 are approximately 5% to approximately 75% of a volume of the composite material 100.

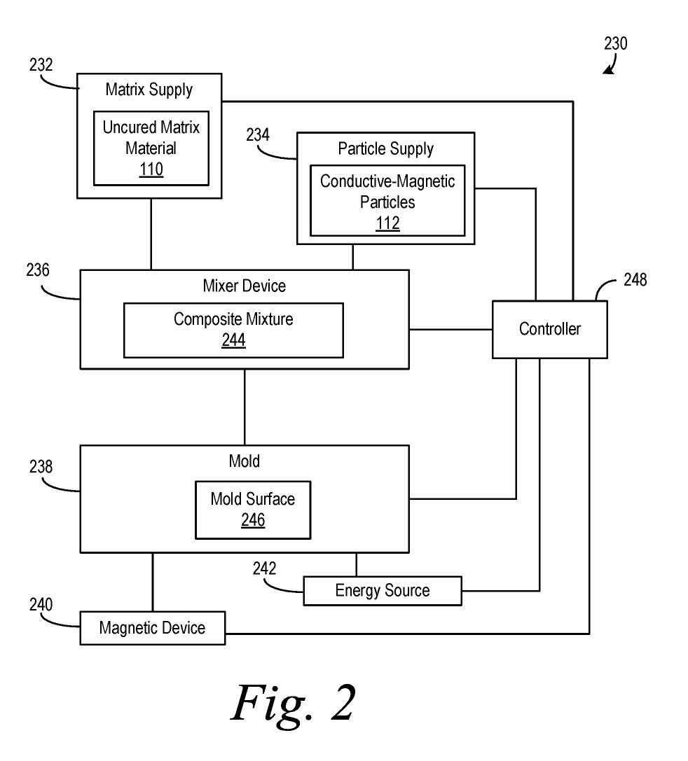

Referring now to FIG. 2, a simplified block diagram of a system 230 for forming the composite material 100 is depicted according to an example embodiment. As shown in FIG. 2, the system 230 includes a matrix supply 232, a particle supply 234, a mixer device 236, a mold 238, a magnetic device 240, and an energy source 242.

The matrix supply 232 can be a container including the matrix material 110 in an uncured state. As noted above, in an uncured state, the matrix material 110 can have a relatively low viscosity to facilitate arranging the conductive-magnetic particles 112 into a particular alignment and/or position within the matrix material 110 during manufacture of the composite material 100. For example, prior to curing the matrix material 110, the matrix material 110 has a viscosity that is configured to allow the plurality of conductive-magnetic particles 112 to move into the alignment responsive to a magnetic field applied by the magnetic device 240 to the conductive-magnetic particles 112.

In one example, the viscosity of the matrix material 110 in the uncured state is less than approximately 1000 centipoise. In another example, the viscosity of the matrix material 110 in the uncured state is less than approximately 200 centipoise. In further examples, the matrix material 110 in the uncured state is between approximately 200 centipoise and approximately 400 centipoise, between approximately 400 centipoise and approximately 600 centipoise, between approximately 600 centipoise and approximately 800 centipoise, or between approximately 800 centipoise and approximately 1000 centipoise.

The particle supply 234 can be a container for containing the conductive-magnetic particles 112. As described above, the conductive-magnetic particles 112 can be a rod-shaped and/or wire-shaped metal structures, which each have a relatively high aspect ratio of the length 118 to the diameter 120.

In this arrangement, the mixer device 236 can receive the matrix material 110 from the matrix supply 232 and the conductive-magnetic particles 112 from the particle supply 234 to facilitate embedding the conductive-magnetic particles 112 in the matrix material 110. For example, the mixer device 236 can mix the matrix material 110 and the conductive-magnetic particles 112 to disperse the conductive-magnetic particles 112 throughout the matrix material 110 and thereby form a composite mixture 244. Within examples, the mixer device 236 can include a centrifugal mixer, a mixing paddle device, a rotating capsule mixing device, a planetary mixer device, an ultrasonic mixer, and/or a shaker device for mixing the conductive-magnetic particles 112 and the matrix material 110 to form the composite mixture 244.

In some examples, the mixer device 236 can supply the composite mixture 244 to the mold 238. In other examples, the mixer device 236 can include the mold 238. For instance, the mold 238 can receive the matrix material 110 from the matrix supply 232 and the conductive-magnetic particles 112 from the particle supply 234, and the mixer device 236 can performing the mixing to form the composite mixture 244 in the mold 238.

In general, the mold 238 is a container, which can contain the composite mixture 244 including the conductive-magnetic particles 112 embedded in the matrix material 110 while the composite mixture 244 cures, and thereby give shape to the resulting composite material 100. As shown in FIG. 2, the mold 238 can include one or more mold surfaces 246, which each define a respective one of the surfaces 114, 116 of the composite material 100.

The magnetic device 240 can apply a magnetic field to the composite mixture 244 in the mold 238. Specifically, the magnetic device 240 can apply the magnetic field to the conductive-magnetic particles 112 in the matrix material 110 to move the conductive-magnetic particles 112 into the alignment in which a longitudinal axis 122 of each conductive-magnetic particle 112 is parallel to a direction of the magnetic field. Accordingly, to align the conductive-magnetic particles 112 with the longitudinal axes 122 perpendicular to the surface 114 of the composite material 100, the magnetic device 240 can apply the magnetic field such that the direction of the magnetic field is substantially perpendicular to the mold surface 246.

Additionally, the magnetic field applied by the magnetic device 240 can also help to distribute the conductive-magnetic particles 112 more evenly throughout the matrix material 110 due to, for example, magnetization of the conductive-magnetic particles 112 generating respective magnetic fields that act on each other. As such, the magnetic field applied by the magnetic device 240 can also reduce or inhibit clumping of the conductive-magnetic particles 112 in the matrix material 110. As examples, the magnetic device 240 can include a permanent magnet and/or an electromagnet. Additionally, as examples, the magnetic device 240 can apply a static magnetic field or an alternating magnetic field. Within examples, the magnetic device 240 can apply the magnetic field at a strength of approximately 0.10 tesla (T) to approximately 10 T.

As noted above, the magnetic device 240 applies the magnetic field to the conductive-magnetic particles 112 while the matrix material 110 cures in the mold 238 to the hardened state, in which the alignment of the conductive-magnetic particles 112 is fixed in the matrix material 110. The energy source 242 can apply energy to the matrix material 110 to facilitate curing the matrix material 110 in the mold 238. In one example, the energy source 242 can apply thermal energy (e.g., heat) to the matrix material 110 to initiate the cure and/or reduce the cure time of the matrix material 110. For instance, the energy source 242 can include an oven that generates and applies the heat to the composite mixture 244 in the mold 238.

In another example, the energy source 242 can apply an ultraviolet (UV) radiation to the matrix material 110 to initiate the cure and/or reduce the cure time of the matrix material 110. For instance, the energy source 242 can include a UV light source that generates and applies the UV radiation to the composite mixture 244 in the mold 238. Within examples, aligning the conductive-magnetic particles 112 can reduce the cross-sectional area of the conductive-magnetic particles 112 parallel to the longitudinal axes 122. This can facilitate the UV radiation passing farther into the composite material 100 to assist in curing the matrix material 110 farther from the surface 114 (e.g., deeper into the matrix material 110).

In one example, the energy source 242 can apply both thermal energy and UV radiation to the matrix material. For instance, the matrix material 110 can include a resign that is configured to be cured by both the thermal energy and the UV radiation. For instance, curing with UV radiation and thermal energy can provide for a surface cure with the UV radiation while exothermic heat initiated by the UV radiation propagates the cure to the lower regions of the matrix material 110, which do not receive the UV radiation due to the conductive-magnetic particles 112. As examples, the resin of the matrix material can include or be adapted from a dental filling resin, which has significant opaque solids in it.

Although the system 230 shown in FIG. 2 includes the energy source 242 to facilitate curing the matrix material 110, the system 230 can omit the energy source 242 in other examples. For instance, in another example, the matrix material 110 can be allowed to cure in an ambient environment without applying energy from an energy source 242 to the composite mixture 244 in the mold 238. In one implementation, the matrix material 110 can be allowed to cure in a room temperature environment while applying the magnetic field to the mold 238.

After the matrix material 110 has cured to a hardened state, the magnetic device 240 can cease the application of the magnetic field to the conductive-magnetic particles 112. As noted above, in the hardened state, the alignment of the conductive-magnetic particles 112 is fixed in the matrix material 110. Thus, after the matrix material 110 cures to the hardened state, the conductive-magnetic particles 112 remain in the alignment even when the magnetic field is removed. As examples, the magnetic field can be removed by deactivating the magnetic device 240 and/or by moving the mold 238 out of the magnetic field generated by the magnetic device 240.

In one example, the composite mixture 244 was formed using a matrix material 110 made of silicon resin and conductive-magnetic particles 112 of nickel microwires. The nickel microwires made up approximately 5% of the volume of the composite mixture 244 and the silicon resin made up approximately 95% of the volume of the composite mixture 244. After embedding the nickel microwires in the uncured silicon resin to form the composite mixture 244, the composite mixture 244 was partially cured overnight at room temperature in a 0.14 T magnetic field applied by a permanent magnet. To increase the rate of curing, the composite mixture 244 and the permanent magnet were placed in an oven, which applied thermal energy to the composite mixture 244 at 50 degrees Celsius. After placing the composite mixture 244 in the oven, the cure was complete in approximately three hours. After curing, it was observed that the nickel microwires were aligned in a common direction, which was perpendicular to the surface 114 of the composite material 100.

As shown in FIG. 2, the system 230 can also include a controller 248. The controller 248 can be communicatively coupled to one or more components of the system 230 (e.g., via wired or wireless communication links) and operable to control operation of those component(s). For instance, in one example, the controller 248 can be operable to activate and/or deactivate the magnetic device 240 and/or the energy source 242. In another example, the controller 248 can be operable to control a supply of the matrix material 110 from the matrix supply 232 and/or a supply of the conductive-magnetic particles 112 from the particle supply 234 to the mixer device 236. For instance, in one implementation, the controller 248 can control operation of one or more valves and/or actuators of the matrix supply 232 and/or particle supply 234 to controllably supply predetermined amounts of the matrix material 110 and/or the conductive-magnetic particles 112 to the mixer device 236 and thereby achieve a desired ratio of matrix material 110 to conductive-magnetic particles 112 for the composite mixture 244.

The controller 248 can be implemented using hardware, software, and/or firmware. For example, the controller 248 can include one or more processors and a non-transitory computer readable medium (e.g., volatile and/or non-volatile memory) that stores machine language instructions or other executable instructions. The instructions, when executed by the one or more processors, cause the system 230 to carry out the various operations described herein. The controller 248, thus, can receive data and store the data in the memory as well.

As noted above, the matrix material 110 has a relatively low viscosity in the uncured state to facilitate aligning the conductive-magnetic particles 112 in the matrix material 110. Within examples, the matrix material 110 can be selected based on one or more criteria including, for example, the viscosity, a pot life, and/or a cure time of the matrix material 110. The pot life of the matrix material 110 is related to an amount of time that can elapse after initiating a cure before the matrix material 110 hardens to an extent at which the conductive-magnetic particles 112 are inhibited from moving into the desired alignment relative to each other and/or the surface 114 of the composite material 100. Accordingly, the matrix material 110 can be selected to have a pot life, which provides time to disperse the conductive-magnetic particles 112 in the matrix material 110, supply the composite mixture 244 to the mold 238, and apply the magnetic field to composite mixture 244.

The cure time of the matrix material 110 is related to an amount of time that is expected to elapse for the matrix material 110 to cure from the uncured state to the hardened state. Thus, when a matrix material 110 has a relatively low cure time, the composite material 100 can be formed more rapidly and efficiently. Within examples, the matrix material 110 can have a cure time of less than approximately 2 hours and/or less than approximately 1 hour. In another example, the matrix material 110 can have a cure time of approximately 10 minutes to approximately 4 hours.

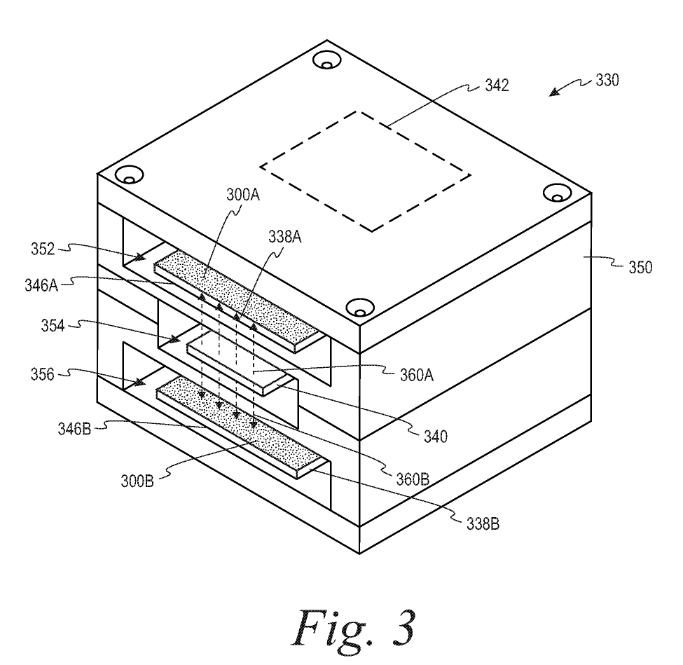

Referring now to FIG. 3, a perspective view of a system 330 for forming the composite material 100 is shown according to an example embodiment. As shown in FIG. 3, the system 330 includes a housing 350 having a plurality of compartments 352, 354, 356. Specifically, the housing 350 includes a first compartment 352 for receiving a first mold 338A and a second compartment 354 for receiving a magnetic device 340. As shown in FIG. 3, the first compartment 352 and the second compartment 354 are arranged relative to each other such that a direction of the magnetic field 360A is substantially perpendicular to a surface 346A of the first mold 338A, which forms a surface of a composite material 300A in the first mold 338A. Also, in FIG. 3, the system 330 includes an energy source 342 that can apply at least one of a thermal energy or an UV light energy to cure the composite material 300A in the first mold 338A.

Additionally, as shown in FIG. 3, the housing 350 includes a third compartment 356 for receiving a second mold 338B. The second compartment 354 and the third compartment are also arranged relative to each other such that a direction of the magnetic field 360B is substantially perpendicular to a surface 346B of the second mold 338B, which forms a surface of a composite material 300B in the second mold 338B. Thus, the housing 350 shown in the example embodiment of FIG. 3 can facilitate simultaneously applying the magnetic field from the magnetic device 340 to both the first mold 338A and the second mold 338B while curing the composite mixtures in the first mold 338A and the second mold 338B. This arrangement can increase manufacturing speeds and efficiencies; however, the housing 350 can omit either the first compartment 352 or the third compartment 356 in another example. Additionally, in other examples, the housing 350 can include more than two compartments 352, 356 to facilitate curing more than two molds 338A, 338B at the same time.

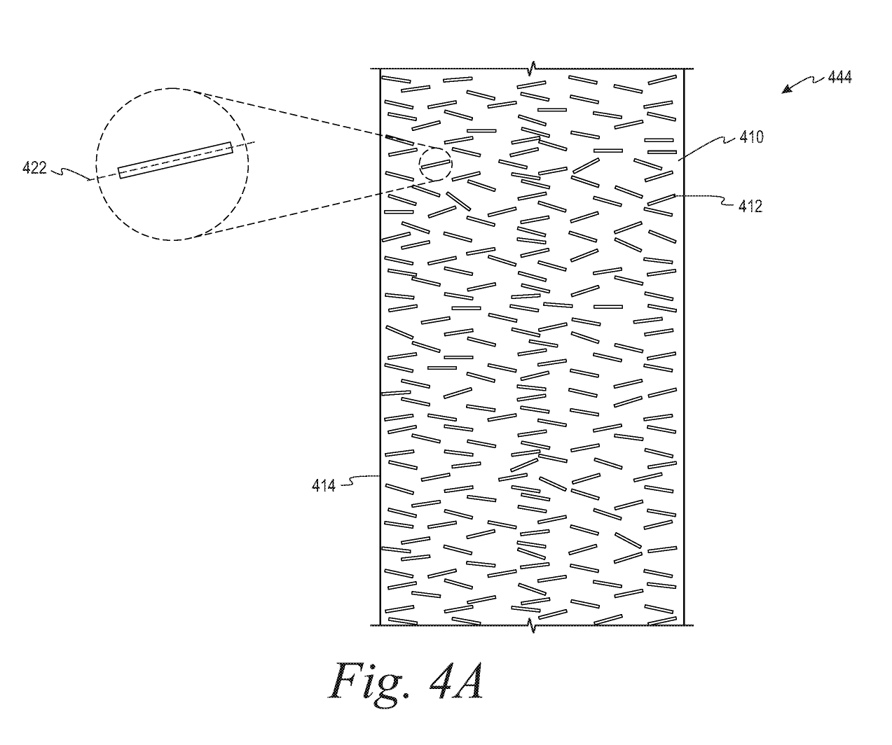

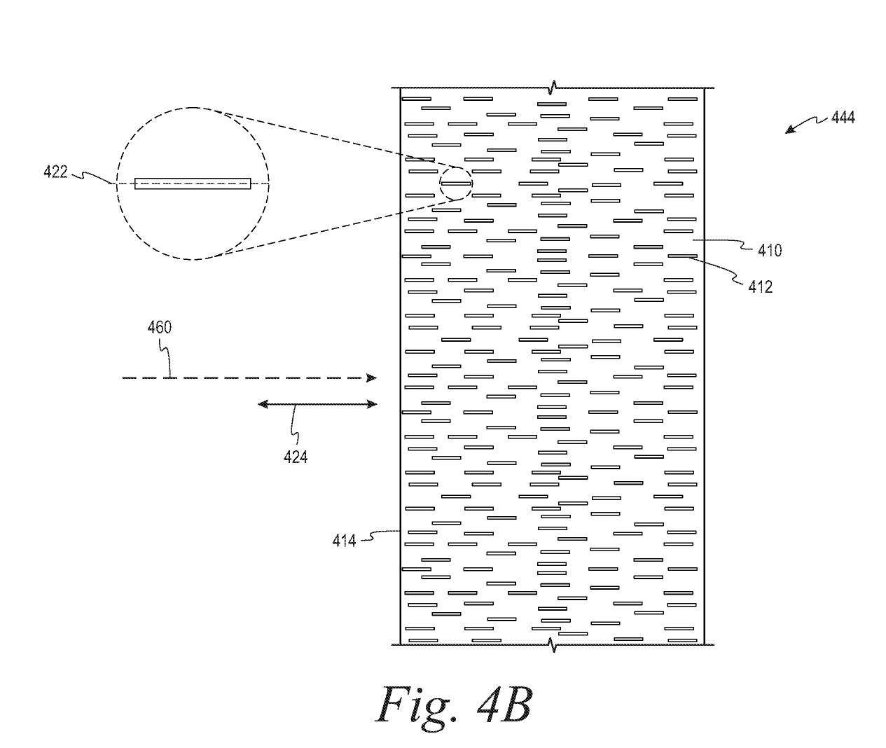

Referring now to FIGS. 4A-4B, cross-sectional views of a composite mixture 444 are depicted at different stages of a manufacturing process according to an example embodiment. Specifically, FIG. 4A depicts the composite mixture 444 prior to applying a magnetic field 460 to a plurality of conductive-magnetic particles 412 embedded in a matrix material 410, and FIG. 4B depicts the composite mixture 444 after applying the magnetic field 460 to the conductive-magnetic particles 412 embedded in the matrix material 410.

As shown in FIG. 4A, prior to applying the magnetic field 460, the conductive-magnetic particles 412 have longitudinal axes 422, which are not aligned in a common direction. Rather, the longitudinal axes 422 are randomly oriented relative to each other and/or a surface 414 of the composite mixture 444.

As shown in FIG. 4B, responsive to the magnetic field 460 applied to the conductive-magnetic particles 412, the conductive-magnetic particles 412 move such that the longitudinal axes 422 are aligned in the common direction 424, which is parallel to the direction of the magnetic field 460. Also, in FIG. 4B, the direction of the magnetic field 460 and the direction 424 of the longitudinal axes 422 are substantially perpendicular to the surface 414 of the composite mixture 444.

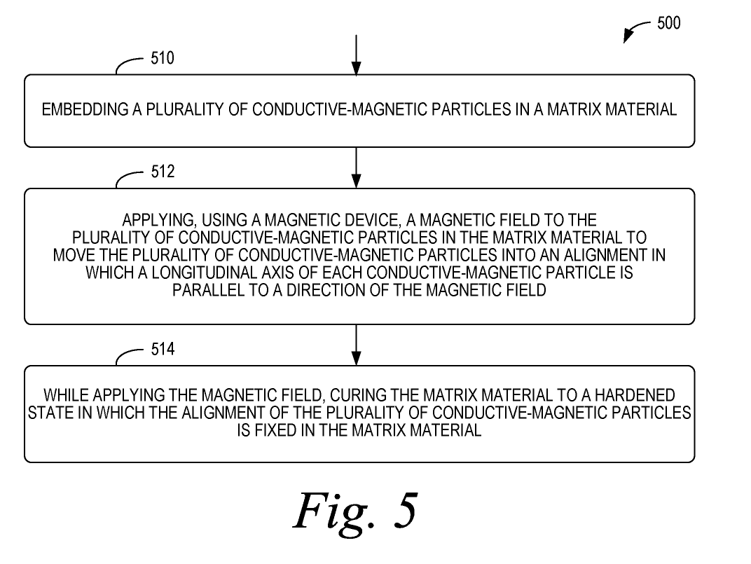

Referring now to FIG. 5, a flowchart for a process 500 for forming a composite material is illustrated according to an example embodiment. As shown in FIG. 5, at block 510, the process 500 includes embedding a plurality of conductive-magnetic particles in a matrix material. At block 512, the process 500 also includes applying, using a magnetic device, a magnetic field to the plurality of conductive-magnetic particles in the matrix material to move the plurality of conductive-magnetic particles into an alignment in which a longitudinal axis of each conductive-magnetic particle is parallel to a direction of the magnetic field. At block 514, the process 500 further includes, while applying the magnetic field, curing the matrix material to a hardened state in which the alignment of the plurality of conductive-magnetic particles is fixed in the matrix material.

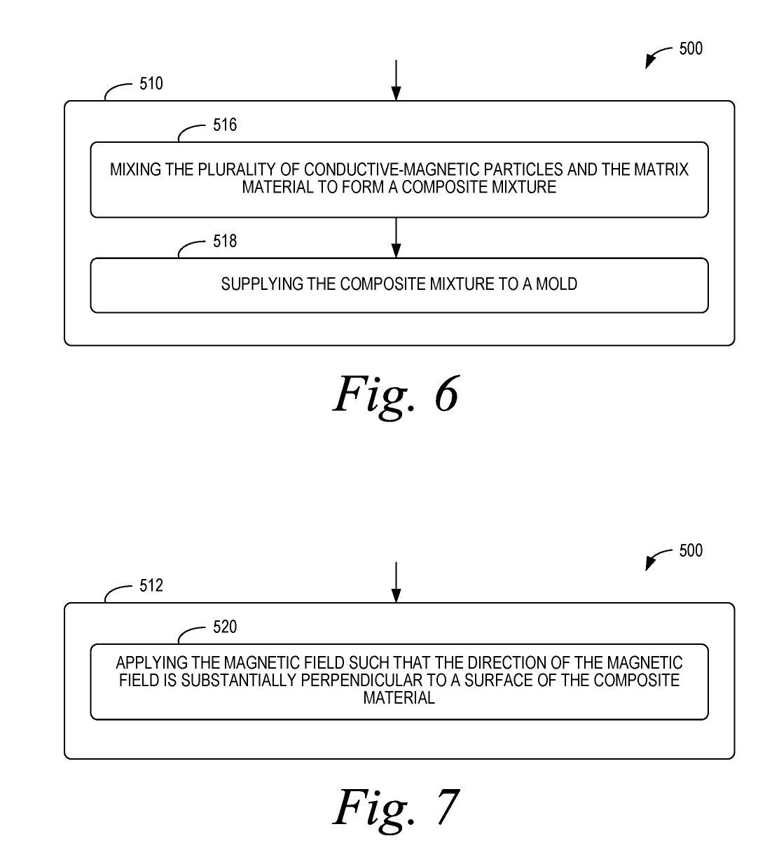

FIGS. 6-9 depict additional aspects of the process 500 according to further examples. As shown in FIG. 6, embedding the plurality of conductive-magnetic particles in the matrix material at block 510 can include mixing the plurality of conductive-magnetic particles and the matrix material to form a composite mixture at block 516 and supplying the composite mixture to a mold at block 518.

As shown in FIG. 7, applying the magnetic field at block 512 can include applying the magnetic field such that the direction of the magnetic field is substantially perpendicular to a surface of the composite material at block 520.

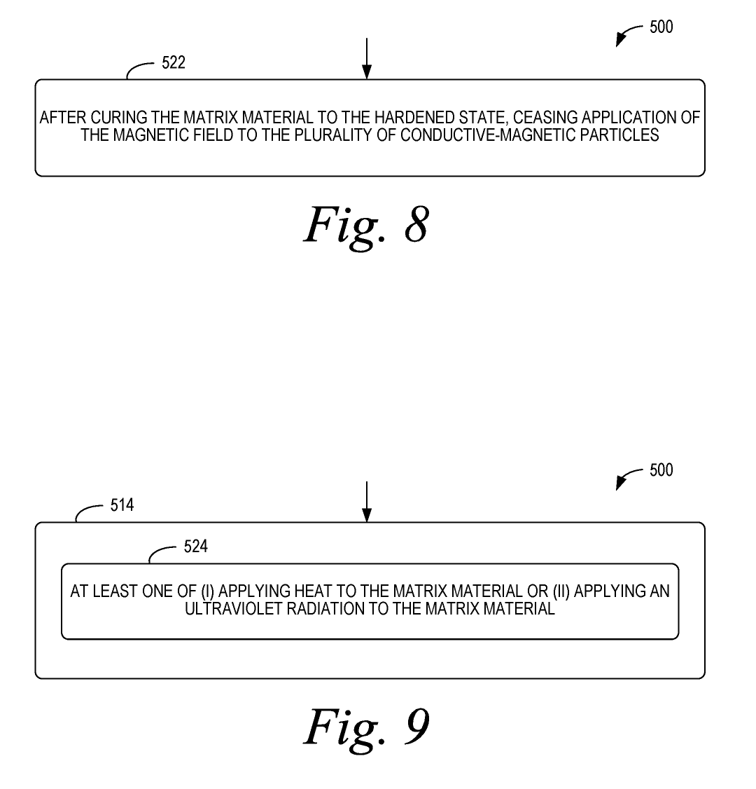

As shown in FIG. 8, the process 500 can also include, after curing the matrix material to the hardened state at block 514, ceasing application of the magnetic field to the plurality of conductive-magnetic particles at block 522.

As shown in FIG. 9, curing at block 514 can include at least one of (i) applying heat to the matrix material or (ii) applying an ultraviolet radiation to the matrix material at block 524.

Any of the blocks shown in FIGS. 6-9 may represent a module, a segment, or a portion of program code, which includes one or more instructions executable by a processor for implementing specific logical functions or steps in the process. The program code may be stored on any type of computer readable medium or data storage, for example, such as a storage device including a disk or hard drive. Further, the program code can be encoded on a computer-readable storage media in a machine-readable format, or on other non-transitory media or articles of manufacture. The computer readable medium may include non-transitory computer readable medium or memory, for example, such as computer-readable media that stores data for short periods of time like register memory, processor cache and Random Access Memory (RAM). The computer readable medium may also include non-transitory media, such as secondary or persistent long term storage, like read only memory (ROM), optical or magnetic disks, compact-disc read only memory (CD-ROM), for example. The computer readable media may also be any other volatile or non-volatile storage systems. The computer readable medium may be considered a tangible computer readable storage medium, for example.

In some instances, components of the devices and/or systems described herein may be configured to perform the functions such that the components are actually configured and structured (with hardware and/or software) to enable such performance. Example configurations then include one or more processors executing instructions to cause the system to perform the functions. Similarly, components of the devices and/or systems may be configured so as to be arranged or adapted to, capable of, or suited for performing the functions, such as when operated in a specific manner.

The description of the different advantageous arrangements has been presented for purposes of illustration and description, and is not intended to be exhaustive or limited to the embodiments in the form disclosed. Many modifications and variations will be apparent to those of ordinary skill in the art. Further, different advantageous embodiments may describe different advantages as compared to other advantageous embodiments. The embodiment or embodiments selected are chosen and described in order to explain the principles of the embodiments, the practical application, and to enable others of ordinary skill in the art to understand the disclosure for various embodiments with various modifications as are suited to the particular use contemplated.

What is claimed is:

1. A method of forming a composite material, comprising:
embedding a plurality of conductive-magnetic particles in a matrix material;
applying, using a magnetic device, a magnetic field to the plurality of conductive-magnetic particles in the matrix material to move the plurality of conductive-magnetic particles into an alignment in which a longitudinal axis of each conductive-magnetic particle is parallel to a direction of the magnetic field; and
while applying the magnetic field, curing the matrix material to a hardened state in which the alignment of the plurality of conductive-magnetic particles is fixed in the matrix material.

2. The method of claim 1, wherein embedding the plurality of conductive-magnetic particles in the matrix material comprises:
mixing the plurality of conductive-magnetic particles and the matrix material to form a composite mixture; and
supplying the composite mixture to a mold, and
wherein applying the magnetic field and curing the matrix material are performed on the composite mixture in the mold.

3. The method of claim 1, wherein prior to curing the matrix material, the matrix material has a viscosity that is configured to allow the plurality of conductive-magnetic particles to move into the alignment responsive to applying the magnetic field to the plurality of conductive-magnetic particles.

4. The method of claim 3, wherein the viscosity is less than approximately 1000 centipoise.

5. The method of claim 3, wherein the viscosity is less than approximately 200 centipoise.

6. The method of claim 1, wherein the plurality of conductive-magnetic particles have an aspect ratio of length to diameter that is greater than 25, and
wherein the longitudinal axis is parallel to the length.

7. The method of claim 1, wherein applying the magnetic field comprises applying the magnetic field such that the direction of the magnetic field is substantially perpendicular to a surface of the composite material.

8. The method of claim 1, further comprising, after curing the matrix material to the hardened state, ceasing application of the magnetic field to the plurality of conductive-magnetic particles.

9. The method of claim 1, wherein curing comprises at least one of (i) applying heat to the matrix material or (ii) applying an ultraviolet radiation to the matrix material.

10. A composite material, comprising:
a matrix material; and
a plurality of conductive-magnetic particles embedded in the matrix material and in an alignment in which a longitudinal axis of each conductive-magnetic particle is parallel to a common direction relative to a surface of the composite material,
wherein each conductive-magnetic particle has a length that is greater than a diameter of the conductive-magnetic particle,
wherein the longitudinal axis is parallel to the length, and
wherein the matrix material electrically isolates the plurality of conductive-magnetic particles from each other.

11. The composite material of claim 10, wherein each conductive-magnetic particle is rod-shaped.

12. The composite material of claim 10, wherein the common direction is substantially perpendicular to a surface of the composite material.

13. The composite material of claim 10, wherein the plurality of conductive-magnetic particles comprise a metallic material.

14. The composite material of claim 13, wherein the metallic material is at least one material selected from a group consisting of: nickel, copper, titanium, iron, cobalt, aluminum, chromium molybdenum, and vanadium.

15. The composite material of claim 10, wherein the length of each conductive-magnetic particle along the longitudinal axis is between approximately 50 microns and approximately 5 millimeters.

16. The composite material of claim 10, wherein the diameter of each conductive-magnetic particle is between approximately 0.1 microns and approximately 100 microns.

17. The composite material of claim 10, wherein the plurality of conductive-magnetic particles comprise approximately 10% to approximately 50% of a volume of the composite material.

18. The composite material of claim 10, wherein the matrix material comprises a resin.

19. A system for forming a composite material, comprising:
a mold configured to contain a composite mixture comprising a plurality of conductive-magnetic particles embedded in a matrix material;
a magnetic device configured to apply a magnetic field to the composite mixture in the mold; and
a housing comprising:
a first compartment configured to receive the mold; and
a second compartment configured to receive the magnetic device,
wherein the first compartment and the second compartment are arranged relative to each other such that a direction of the magnetic field is substantially perpendicular to a surface of the mold, which forms a surface of the composite material.

20. The system of claim 19, further comprising an energy source configured to apply at least one of a thermal energy or an ultraviolet (UV) light energy to cure the composite mixture in the mold.
